(19) United States
(12) Patent Application Publication
(10) Pub. No.: US 2016/0082552 A1
(43) Pub. Date: Mar. 24, 2016

(54) ZN BASED LEAD-FREE SOLDER AND SEMICONDUCTOR POWER MODULE

(71) Applicant: MITSUBISHI ELECTRIC CORPORATION, Tokyo (JP)

(72) Inventor: Koji YAMAZAKI, Chiyoda-ku (JP)

(73) Assignee: MITSUBISHI ELECTRIC CORPORATION, Chiyoda-ku (JP)

(21) Appl. No.: 14/890,202

(22) PCT Filed: Dec. 13, 2013
(86) PCT No.: PCT/JP2013/083448

§ 371 Date: Nov. 10, 2015

(30) Foreign Application Priority Data
Jun. 20, 2013 (JP) 2013-129243

(51) Int. Cl. B23K 35/28; H01L 23/31; H01L 23/00; C22C 18/00

(52) U.S. Cl. CPC B23K 35/282; C22C 18/00; H01L 23/3171; H01L 24/08; H01L 2224/05618; H01L 2224/04042; H01L 2924/014; H01L 2224/08225; H01L 2924/0103; H01L 2924/01024; H01L 2924/01013; H01L 2924/01051; H01L 2924/01032; H01L 2924/01031; H01L 2924/01025; H01L 2924/01049; H01L 2924/01083; H01L 2924/0105; H01L 2924/01015; H01L 2924/01023; H01L 2924/01014

(57) ABSTRACT

Zn based lead-free solder is obtained in which its range of practical melting points is between 300° C. and 350° C. The Zn based lead-free solder includes a Cr content of 0.05 through 0.2 wt %, an Al content of 0.25 through 1.0 wt %, an Sb content of 0.5 through 2.0 wt %, a Ge content of 1.0 through 5.8 wt %, and a Ga content of 5 through 10 wt %; or the Zn based lead-free solder includes a Cr content of 0.05 through 0.2 wt %, an Al content of 0.25 through 1.0 wt %, an Sb content of 0.5 through 2.0 wt %, a Ge content of 1.0 through 5.8 wt %, and an In content of 10 through 20 wt %.

### TECHNICAL FIELD

The present invention relates to Zn based lead-free solder suitably used for bonding between a substrate and a semiconductor component, and relates to a semiconductor power module made by using the Zn based lead-free solder.

### BACKGROUND ART

Requirements for reliability on semiconductor devices become more advanced in recent years. In particular, higher reliability is strongly required for a bonded portion between a semiconductor element and a circuit board or substrate, those having a large difference of coefficients of thermal expansion. As for the semiconductor element, silicon (Si) and gallium arsenide (GaAs) have been widely used as substrates. The range of their operating temperatures is between 100° C. and 125° C. As solder materials to bond these substrates to electrodes of an electronics circuit, 95Pb-5Sn solder (% by mass) or the like is used for Si devices, and 80Au-20Sn solder (% by mass) or the like is used for gallium arsenide devices. For the solder materials, required are cracking withstand capability against cyclic thermal stress, melting-point compatibility for coping with multiple-stage solder bonding at the time of assembly, and what is more, device's contamination resistance, or the like. The cyclic thermal stress is originated in the difference of thermal expansion between the semiconductor element and a circuit board or substrate.

However, reducing the usage of the 95Pb-5Sn solder containing a large amount of hazardous lead (Pb) is in progress from the viewpoint of relieving the environmental load. In addition, replacement for the 80Au-20Sn solder is strongly desired in terms of soaring prices of precious metals and the amounts of their reserves. Meanwhile, from the viewpoint of energy conservation, active developments have been underway for the devices utilizing substrates made of silicon carbide (SiC) and gallium nitride (GaN) as next-generation devices. From the viewpoint of reducing losses, these devices are presumed to function at an operating temperature of 175° C. or more, and it is also said that they will operate at 300° C. in the future.

In order to fulfill the aforementioned requirements, a high temperature solder-material is required which has a high melting point and also excels in heat resistance. As in such solder, Pb dominant solder having a melting temperature in the neighborhood of 300° C. has been hitherto used. For example, known solder is Pb-10Sn solder (solidus temperature of 268° C., liquidus temperature of 302° C.), Pb-5Sn solder (solidus temperature of 307° C., liquidus temperature of 313° C.), Pb-2Ag-8Sn solder (solidus temperature of 275° C., liquidus temperature of 346° C.), Pb-5Ag solder (solidus temperature of 304° C., liquidus temperature of 365° C.), or the like.

The aforementioned solder is in each case Pb basis solder containing Pb as its main ingredient. Recently, from a viewpoint of the environmental protection, lead-free solder is required to be used, in place of the Pb based solder, in the soldering technologies as a whole. As a matter of course, the usage of lead-free solder is under consideration also for the aforementioned Pb—Sn based high temperature solder having been used for semiconductor devices. Up to this time, various kinds of lead-free solder have been proposed; however, the majority of proposals is Sn based solder containing tin (Sn) as its main ingredient.

For example, in Sn—Ag based solder whose solidus temperature (eutectic temperature) is 221° C., the liquidus temperature rises in accordance with the increase of a silver (Ag) content; however, the solidus temperature rises very little. It seems that such high temperature solder is not found at its solidus temperature of 260° C. or more. In Sn—Sb based solder of a solidus temperature of 227° C., the liquidus temperature significantly rises also when antimony (Sb) is significantly increased in its content in order to raise the solidus temperature. However, even when another element is added to those described above, such characteristics are not subjected to changes. Therefore, it may be understood that there does not exist Sn based lead-free solder which does not melt even at 300° C. suitable for practical use.

As a bonding technology which does not use the high temperature solder up to this time, Zn based solder containing zinc (Zn), in place of Sn, as its main ingredient has been considered. For example, in Patent Document 1, there mixed into basic composition in which an aluminum Al content of 1 to 10% by weight is mixed into Zn, is one, or two or more of those ingredients selected from among Ga (0.001 to 1% by weight), In (0.1 to 10% by weight), Ge (0.001 to 10% by weight), Si (0.1 to 10% by weight), and Sn (0.1 to 10% by weight) which are the additive ingredients for improving a wetting property. In addition, Zn based lead-free solder is disclosed into which Mn and/or Ti having an effect to suppress oxidation of a solder bonded portion is additionally mixed in an amount of 0.0001 to 1% by weight.

In Patent Document 2, lead-free solder containing Zn as its main ingredient is disclosed in which the lead-free solder contains 3.0 to 7.0% by mass of Al, contains 0.005 to 0.500% by mass of P, and further contains at least one of Mg and Ge. Here, in a case of Mg, the content is 0.3 to 4.0% by mass, and in a case of Ge, 0.3 to 3.0% by mass. In addition, lead-free solder containing Zn as its main ingredient is disclosed in which the lead-free solder is characterized to contain 1.0 to 9.0% by mass of Al, and contain 0.002 to 0.800% by mass of P; and a remaining portion of the lead-free solder is made of Zn, where inevitable elements are included in the remaining portion upon manufacturing.

### RELATED ART DOCUMENTS

### Patent Documents

[Patent Document 1] Japanese Laid-Open Patent Publication No. 2012-183558

[Patent Document 2] Japanese Laid-Open Patent Publication No. 2012-121053

### Non Patent Document

[Non-Patent Document 1] Toshihiro MATSUNAGA, and three persons, “Evaluation of Fatigue Life Reliability and New Lead Bonding Technology for Power Modules” [online], May, 2005 (Vol. 79, No. 7), p. 19 (p. 447), Mitsubishi Denki Giho, Tokyo, the Internet <URL: http://www.mitsubishielectric.co.jp/giho/0507/0507106.pdf>

### SUMMARY OF THE INVENTION

### Problems to be Solved by the Invention

A bonded portion between a general semiconductor element and a substrate is put under consideration. On a surface of the semiconductor element, there usually exist electrodes referred to as bonding pads for carrying out the wiring by wire bonding. Their peripheral portions are required to have insulation, so that, on the surface of the semiconductor element, a protective resin film such as a polyimide film having moderate insulation properties and high heat resistance is formed as a protection film. The protection film made of polyimide whose decomposition temperature is 500° C. or more has very high heat resistance. An adhesion property between the polyimide film and the element is not very high in performance, so that, at 350° C., peeling of the polyimide film occurs.

In the Zn based solder disclosed in Patent Documents 1 and 2, its composition is known in which a melting point exceeds 350° C. When Zn based solder of the composition whose melting point exceeds 350° C. is used, the polyimide film peels off due to the temperature at the time of bonding. Because the melting point of Zn based solder is high, insulation properties between adjacent wires each other are not maintained for a semiconductor element even when the semiconductor element is bonded to a substrate. Because an operating temperature of the semiconductor element becomes on the order of 300° C., the Zn based solder should not melt under operating conditions, and the polyimide film should not easily peel off. From the viewpoints described above, the developments are desired for Zn based lead-free solder whose melting points are 300° C. through 350° C.

### Means for Solving the Problems

First Zn based lead-free solder according to the present invention comprises: a chromium Cr content of 0.05 through 0.2% by mass; an aluminum Al content of 0.25 through 1.0% by mass; an antimony Sb content of 0.5 through 2.0% by mass; a germanium Ge content of 1.0 through 5.8% by mass; and a gallium Ga content of 5 through 10% by mass.

Second Zn based lead-free solder according to the present invention comprises: a chromium Cr content of 0.05 through 0.2% by mass; an aluminum Al content of 0.25 through 1.0% by mass; an antimony Sb content of 0.5 through 2.0% by mass; a germanium Ge content of 1.0 through 5.8% by mass; and an indium In content of 10 through 20% by mass.

Third Zn based lead-free solder according to the present invention comprises: a chromium Cr content of 0.05 through 0.2% by mass; an aluminum Al content of 0.25 through 1.0% by mass; a manganese Mn content of 0.6 through 1.2% by mass; a germanium Ge content of 1.0 through 5.8% by mass; and a gallium Ga content of 5 through 10% by mass.

Fourth Zn based lead-free solder according to the present invention comprises: a chromium Cr content of 0.05 through 0.2% by mass; an aluminum Al content of 0.25 through 1.0% by mass; a manganese Mn content of 0.6 through 1.2% by mass; a germanium Ge content of 1.0 through 5.8% by mass; and an indium In content of 10 through 20% by mass.

A semiconductor power module according to the present invention comprises: a power semiconductor element bonded on a substrate by any one of the first Zn based lead-free solder through the fourth Zn based lead-free solder; a bonding pad formed on a main surface of the power semiconductor element; a resin film for coating the main surface of the power semiconductor element; and a bonding wire connected to the bonding pad.

### Effects of the Invention

According to the present invention, it becomes possible to obtain Zn based lead-free solder whose range of practical melting points is between 300° C. and 350° C. In addition, it becomes possible to obtain a semiconductor power module whose thermal resistance is enhanced between a substrate and a power semiconductor element.

### BRIEF DESCRIPTION OF DRAWINGS

FIG. 1 is a schematic model diagram illustrating a semiconductor power module used in embodiments of the present invention;

FIG. 2 is a diagram showing the characteristics of additive elements for Zn based lead-free solder considered according to the present invention;

FIG. 3 is a diagram indicating consideration results of Exemplary Embodiments 1 through 16;

FIG. 4 is a diagram indicating consideration results of Exemplary Embodiments 17 through 32; and

FIG. 5 is a diagram indicating consideration results of Comparative Examples 1 through 16.

### EMBODIMENTS FOR CARRYING OUT THE INVENTION

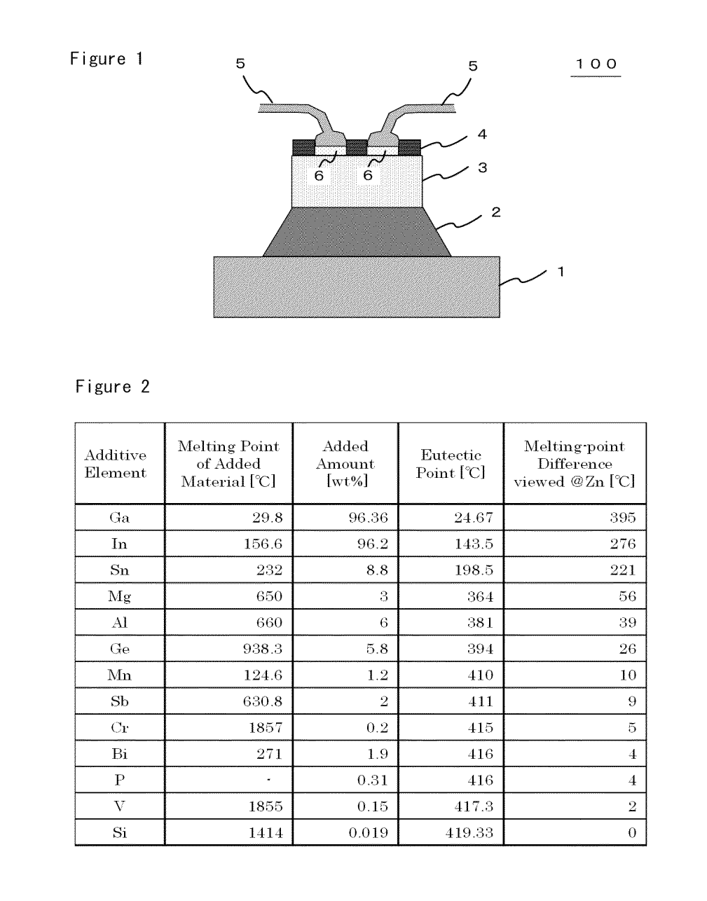

Bonded portions of a semiconductor power module 100 according to the present invention are illustrated in FIG. 1. As for a substrate 1, a DBC (Direct Bonded Copper) substrate or the like is used. The substrate 1 and a power semiconductor element 3 are bonded to each other by Zn based lead-free solder 2 according to the present invention. On a surface of the power semiconductor element 3, bonding pads (or electrodes) 6 are formed.

On peripheral portions of the bonding pads 6, a resin film 4 is formed which has moderate insulation properties, and high heat resistance. To the bonding pads 6, bonding wires 5 are connected. The Zn based lead-free solder according to the present invention can also be used for bonding wiring-lead terminals.

As for the resin film 4, a polyimide resin, a phenolic resin, a poly-phenylene-benzobisoxazole (PBO: Poly-Phenylene-BenzobisOxazole) resin, a silicone resin, and the like are used. A polyimide film whose decomposition temperature is 500° C. or more has very high heat resistance; however, an adhesion property between the polyimide film and the power semiconductor element 3 is not very high in performance. When an operating temperature of the semiconductor power module 100 becomes 350° C. or more, the polyimide film peels off.

As for the power semiconductor element 3, not only an element formed by silicon (Si), but also an element formed by a wide band-gap semiconductor whose band-gap is wider in comparison with silicon can be suitably used. As the wide band-gap semiconductor, silicon carbide (SiC), a gallium nitride-based material, diamond, or the like can be named. When the wide band-gap semiconductor is used, a device utilizing the power semiconductor element 3 can be small-sized because its allowable current density is high, and also electric power losses are low.

In FIG. 2, the characteristics of elements each having a eutectic point with Zn are shown. Because the melting point of zinc itself is 420° C., an element(s) having a eutectic point with Zn, or a low melting-point element(s) is to be added to a suitable amount in order to make Zn based lead-free solder. Among those elements, an additive element which is the most effective for bringing a melting point into 300° C. through 350° C. is magnesium Mg that demonstrates a eutectic point of 364° C. in an amount of 3 wt %. However, when Mg is added, the solder becomes hard and brittle, and also becomes easy to be oxidized. Even with its added amount of substantially 0.1 wt %, an initial bonding property of solder and a heat cycle property thereof are reduced to a large degree. For these reasons, it is decided not to actually add Mg, though it is very effective to lower the melting point.

As another element for lowering the melting point of Zn based solder, aluminum Al has a eutectic point in an amount of 6 wt %. Because Al is a material that is easier to be oxidized than Zn though not to the extent of Mg, an initial bonding property of solder is reduced when Al is added thereto. However, because Al is a relatively soft material, the solder exhibits satisfactory heat cycle property. To this end, it is determined that the added amount of Al is restricted to the degree not to reduce the initial bonding property. In Patent Document 1, Al is added in such an amount of 1 to 10% by weight. In the added amount as such, the initial bonding property is reduced to a large degree, and thus, it is decided to set an added amount of Al substantially less in its content than 1% by mass.

In Patent Document 2, Al is added in an amount of 3.0 to 7.0% by mass, and Mg, in an amount of 0.3 to 4.0% by mass. Because, in such an added amount, an initial bonding property and a heat cycle property are reduced to a large degree, it is decided that the added amount of Al is set substantially less than 1% by mass. Because it is desirable that Mg is not added, Mg is not added to Zn in the embodiment 2 of the present invention. By curbing the added amount of Al and by adjusting other additive elements, it is aimed at obtaining Zn based solder, containing Zn as its main ingredient, whose melting point stays in the range between 300° C. and 350° C. Moreover, by putting a heat cycle property and an initial bonding property as determinant indicators, the optimization of solder composition is thence carried out.

In order to make predetermined solder, Zn, Al, Ge, Mn, Sb and Cr were prepared as raw materials each having a purity of 99.9% by mass or higher. As for large flaky and/or bulky raw materials, they were made finer to the sizes of 3 mm or less by cutting, grinding and the like, while considering fulfilling the requirements in an alloy after being melted so that there would not be variations in the composition depending on sampling places, and the composition would become uniform. Next, predetermined amounts were weighed from these raw materials, and weighed ones were placed into a crucible made of graphite for a high-frequency melting furnace.

The crucible containing each of the raw materials was entered into the high-frequency melting furnace, and was heated for melting them within the furnace in a nitrogen ambient (nitrogen flow rate: 0.5 L/min) so as to suppress oxidation. When the metals started melting, they were stirred up with an intermixing rod(s), and were uniformly mixed so that local variations in the composition did not occur. After having confirmed that they were sufficiently melted, a high-frequency power source was switched off; immediately, the crucible was taken out, and the molten liquid in the crucible was poured into a mold for a solder master alloy. As for the mold, a similar one was used which had a shape generally utilized for manufacturing solder master alloys.

According to the above, forty-eight kinds of Zn based solder master alloys were made by altering an intermixing ratio of each of the raw materials described above. For each of the solder master alloys having been obtained, cuttings were collected by a drill, and they underwent quantitative analysis by emission analysis. As a result, it had been verified that each kind of the solder contained the additive elements in the values as intended. In addition, it had been verified that, by a visual check, there were not a void, a shrinkage cavity, significant cracking (surface deficiency), and discoloration in the Zn based solder master alloys.

Next, for the molded samples described above, several tens of milligrams were extracted in the order approximately from their central portions, and, using differential scanning calorimetry (DSC: Differential Scanning calorimetry) apparatus, solidus temperatures for each kind of the solder were measured as effective melting points. Melting point analysis was performed in such a manner that the samples were first bonded by once subjecting them to heat, and then they were twice subjected to heat, for the sake of the verification if they did not subsequently melt by heating or not. As for a measurement temperature profile, 15° C. was defined as measurement start point, and rise-of-temperature was performed at 10° C./min to reach up to 400° C. Subsequently, cooling was provided at 5° C./min. If the scanning-operation was performed only once, a peak which differed from a true one might give rise to occur due to influences of impurities remaining in the interior and/or surface-adhered substance. It was more preferable to perform twice as described above, because the temperature states conformed to an actual profile. These measurements also included the evaluation if remelting occurred or not after having been once bonded.

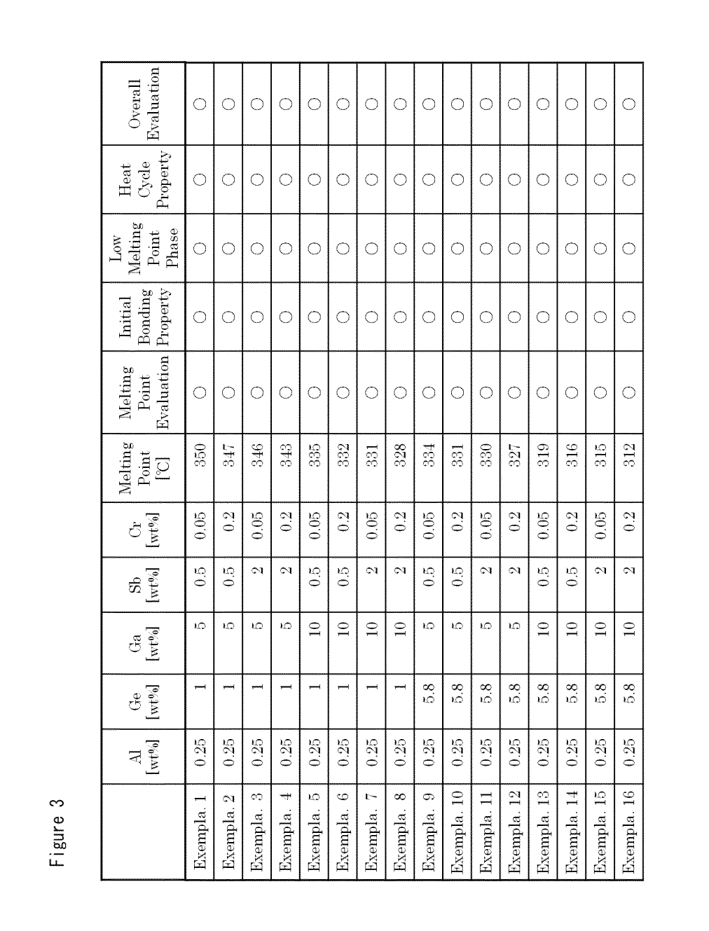

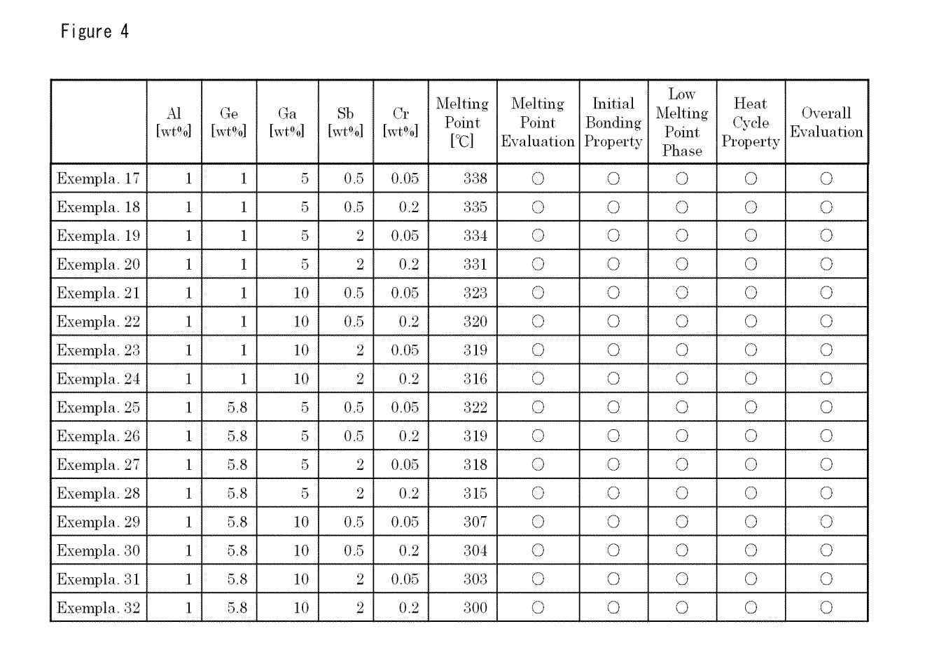

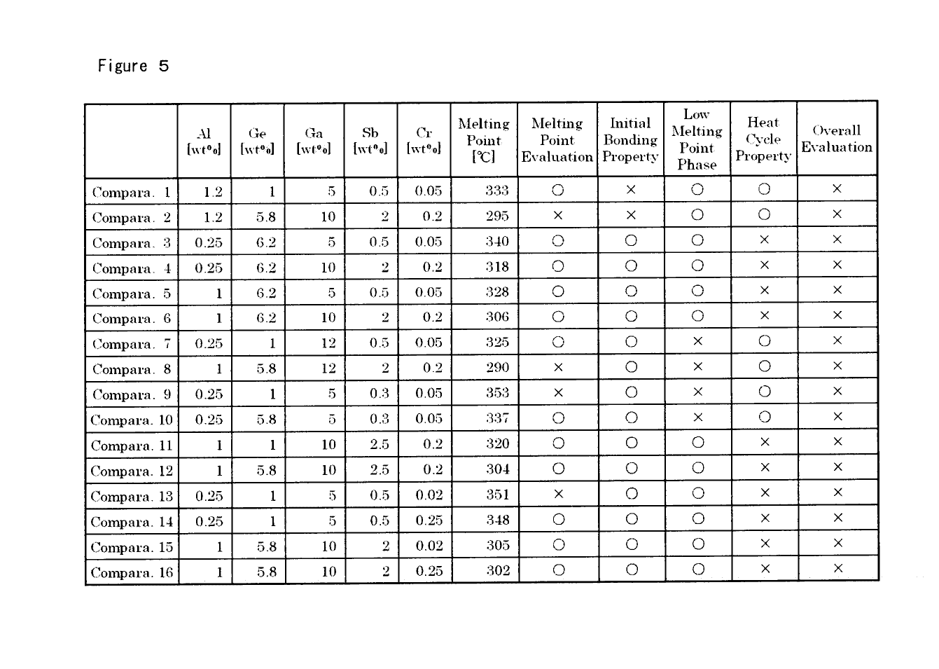

Under the conditions described above, the measured results of the solidus temperatures are indicated for each of the solder master alloys in the melting point columns of FIG. 3 through FIG. 5 (Exemplary Embodiments 1 through 32, and Comparative Examples 1 through 16). If the melting point of Zn based solder stayed within the range between 300° C. and 350° C., a melting-point evaluation was made as “∘,” and, in other cases, the melting-point evaluation was made as “×.” In addition, there were some cases in which, during the measurement of the solidus temperatures, clear peaks were observed in the vicinity of a melting point of Ga (30° C.) being added, or in the vicinity of a eutectic point with Zn. When a peak was observed, it could be understood that a low melting-point phase might exist even after actual bonding. In the columns of the low melting-point phase of FIG. 3 through FIG. 5, symbol “×” indicates when a peak of a low melting point was observed, and symbol “∘,” when a peak of a low melting point was not observed.

Next, each of the solder master alloys was rolled, and formed solder of the thickness 0.3 mm (size: 20 mm×20 mm) was made. In addition, a DBC (Direct Bonded Copper) substrate of the thickness 1.2 mm and an SiC element of the thickness 0.25 mm were bonded to each other in a hydrogen reducing ambient at the sample's temperature of 350° C. (10 min). Here, the DBC substrate corresponds to the substrate 1 in FIG. 1, and the SiC element, to the power semiconductor element 3 in FIG. 1. The structure of the DBC substrate (coefficient of thermal expansion α: 10 ppm) was made such that copper (Cu) plate: Si₃N₄ insulating plate: Cu plate=0.4 mm:0.32:0.4 mm. The SiC element (coefficient of thermal expansion α: 4 ppm, size: 20 mm×20 mm) was metallized with gold (Au) on its outermost surface. On an every composition basis, five samples were made. After having bonded, a void fraction (white portions) was calculated by scanning acoustic tomograph (SAT: Scanning Acoustic Tomograph) observation. When all of the void fractions were 20% or less, an initial bonding property is indicated by symbol “∘,” and, when any one of them was larger than 20%, an initial bonding property, by symbol “×.”

Next, in order to evaluate a heat cycle property, it was decided to simulate more actual operations. In regard to bonded samples of the DBC substrates with the SiC elements, heat cycle processing was performed by setting an upper-limit temperature at 300° C. and a lower-limit temperature at 100° C. in a cycle number of 30 thousand times, where one cycle lasts for 15 seconds. Note that, a heat cycle apparatus which could perform a cycle in such a short time was not commercially available, so that a Mitsubishi Electric Corporation's original apparatus was used to perform the processing (refer to Non-Patent Document 1). After the heat cycles, the degree of cracking development was investigated by SAT observation on the samples. Because cracking positions also showed white in an SAT image, the degree of cracking development was calculated by subtracting a ratio of white positions (initial voids+cracking) calculated from an SAT image after the heat cycles, from that of white positions (initial voids) calculated from an SAT image observed in an initial bonding state.

When the difference between the ratios was less than 50% of a bonded portion in total, the columns of heat cycle property in the figures were indicated as “∘,” and, when the difference was more than 50%, they were indicated as “×.” With respect to the thermal conductivity of Zn which is about 120 W/m·K, the thermal conductivity of Sn-3Ag-0.5Cu solder generally used up to this time is in the degree of 60 W/m·K, and that of Pb-5Sn solder, 35 W/m·K. In this time, a threshold value of heat cycle property was set at 50%; this is because a decision was made in which the superiority could be drawn in that the thermal conductivity of Zn based solder was good, if its cracking did not develop approximately by half in the bonded portion.

Accordingly, when any one of the melting-point evaluation, the presence or absence of a low melting-point phase, the initial bonding property and the heat cycle property was marked with symbol “×,” an overall evaluation was indicated as “×,” and, when all of the given criteria were satisfied, an overall evaluation was indicated as “∘”; the results are described in the columns of overall evaluation in the figures. In Exemplary Embodiments 1 through 32, their overall evaluation was “∘.” In Comparative Examples 1 through 16, their overall evaluation was “×.” As a result, good results were obtained, in the main ingredient of Zn, by containing 1.0 through 5.8 wt % of Ge, by containing 0.05 through 0.2 wt % of Cr, by containing 0.25 through 1.0 wt % of Al, by containing 5 through 10 wt % of Ga, and by containing 0.5 through 2.0 wt % of Sb. Next, for individual composition, the explanation will be made below for the reasons why such added amounts described above are specified.

Al (0.25 through 1.0 wt %)

Reasons: a eutectic point with Zn is at 6 wt %. Because Al is easy to be oxidized, its amount is required to be decreased as much as possible. When an added amount of Al is on the order of 1 wt % or so, oxidation is also suppressed, and in addition, the eutectic gets closer, so that a lower melting point is achieved. In a case in which an Al content is less than 0.25 wt %, it can be easily estimated from the results of melting-point measurements for each composition in the figures that a lowering melting-point effect cannot be obtained, so that the melting point exceeds 350° C. Meanwhile, if the Al content is more than 1 wt % (Comparative Example 1, Comparative Example 2), a good bonding state cannot be obtained because a void fraction exceeds 20% at the time of initial bonding due to an influence of oxidation. Accordingly, it is preferable to set an added amount of Al at 0.25 through 1.0 wt %.

Ge (1.0 through 5.8 wt %)

Reasons: because a eutectic point with Zn is at 5.8 wt %, it can be easily estimated from the results of melting-point measurements for each composition in the figures that, if a Ge content is less than 1 wt %, a lowering melting-point effect is small, so that the melting point exceeds 350° C. Meanwhile, if the Ge content is more than 5.8 wt %, which exceeds a eutectic point, so that a high melting point is brought about. In addition, because significantly gross precipitates are increased, the solder master alloys have become hard and brittle, and degradation in the heat cycles has been predominantly accelerated, so that the development of cracking exceeds 50% (Comparative Example 3 through Comparative Example 6). Accordingly, it is preferable to set an added amount of Ge at 1.0 through 5.8 wt %.

Ga (5 through 10 wt %)

Reasons: because Ga itself has a low melting point, the melting point is moderately lowered by adding Ga in its content of 5 wt % or more. In a case in which a Ga content is less than 5 wt %, it can be easily estimated from the results of melting-point measurements for each composition in the figures that a lowering melting-point effect cannot be obtained, so that the melting point exceeds 350° C. Meanwhile, when the Ga content is more than 10 wt % (Comparative Example 7, Comparative Example 8), the melting point becomes lower than 300° C. due to the excessive addition. In addition, because low melting-point phases of Ga alone and eutectic with Zn have been observed from DSC measurement results, these are not preferable. Accordingly, it is preferable to set an added amount of Ga at 5 through 10 wt %. Here, an added amount of the Ga is indicated by a value after one decimal place is rounded off to the closest integer.

Sb (0.5 through 2.0 wt %)

Reasons: because a eutectic point with Zn is at 2 wt %, Sb possesses a lowering melting-point effect on the order of 10° C., which is smaller in comparison with the aforementioned Al, Ge and Ga. In a case in which an Sb content is less than 0.5 wt % (Comparative Example 9, Comparative Example 10), a low melting-point effect cannot be obtained. In addition, because low melting-point phases of Ga alone and Ga—Zn eutectic have been observed in DSC results, the case is not preferable. Meanwhile, when the Sb content is larger than 2 wt % (Comparative Example 11, Comparative Example 12), the formation of low melting-point phase is curbed; however, due to the excessive addition, significantly gross precipitates have been increased. The solder master alloys have become hard and brittle, and degradation in the heat cycles has been predominantly accelerated, so that the development of cracking exceeds 50%. The details are not made clear about such a mechanism that the low melting-point phase was curbed by adding Sb to a suitable amount as described above; however, it may be probably understood that Sb and Ga formed an alloy phase (Sb—Ga or the like) of a high melting point, so that the formation of low melting-point phase was curbed. Accordingly, it is preferable to set an added amount of Sb at 0.5 through 2.0 wt %.

Cr (0.05 through 0.2 wt %)

Reasons: a eutectic point with Zn is at 0.2 wt %, and Cr possesses a lowering melting-point effect on the order of 5° C. In a case in which a Cr content is less than 0.05 wt % (Comparative Example 13, Comparative Example 14), good results cannot be obtained in a heat cycle property. This is because the eutectic structure of Zn—Cr is fine to a large extent when Cr is added to Zn to a suitable amount, it can be understood that the ductility is enhanced, and, according to fine dispersion effect, cracking is difficult to be developed even when thermal strain is subjected to. According to the above, Cr exerts a distinctive enhancement effect on the heat cycle property. Meanwhile, when the Cr content is larger than 0.2 wt % (Comparative Example 14, Comparative Example 15), the solder master alloys have become hard and brittle because significantly gross precipitates are increased due to the excessive addition. Degradation in the heat cycles has been predominantly accelerated, so that the development of cracking exceeds 50%. Accordingly, it is preferable to set an added amount of Cr at 0.05 through 0.2 wt %.

In the Zn based lead-free solder according to the present invention, it may be adopted that In, Sn, Bi, Mn, P, V and/or Si which can lower the melting point are added as additive elements other than Al, Ge, Ga, Sb and Cr. Especially, as an additive element which demonstrates similar effects to the aforementioned Sb, manganese Mn can be named. To be specific, when Mn is added by 0.6 wt % or more, an alloy phase of a high melting point is partially made, so that the formation of low melting-point phase due to the addition of Ga is curbed. If Mn is added more than 1.2 wt %, excessive Mn precipitates in accordance with an effect to curb the Ga phase, so that the solder becomes hard and brittle. Accordingly, it is preferable to set the Mn content at 0.6 through 1.2 wt %.

Moreover, as an additive element which demonstrates similar effects to the aforementioned Ga, indium In can be named. To be specific, if an In content is less than 10 wt %, a lowering melting-point effect cannot be obtained, so that the melting point exceeds 350° C. On the other hand, in a case in which the In content is more than 20 wt %, the melting point becomes less than 300° C. due to the excessive addition. Additionally, because low melting-point phases of In alone and In—Zn eutectic have been observed from DSC measurement results, the case is not preferable. Accordingly, it is preferable to set an added amount of indium In at 10 through 20 wt %. In such cases, the Zn based lead-free solder according to the present invention has the melting point of effective 300° C. through 350° C. Here, an added amount of the In is indicated by a value after one decimal place is rounded off to the closest integer.

In the Zn based lead-free solder according to the present invention, Mg is not added which is easy to be oxidized, and, with a small amount of its addition, the solder easily becomes hard and brittle, though Mg is effective to lower the melting point. Meanwhile, the structure of Zn is made finer by the addition of Cr, and the heat cycle property is enhanced. Additionally, because the melting point is to be lowered by the addition of Al, which is but easy to be oxidized, the initial bonding property is satisfied by setting an added amount of Al at 1 wt % or less. Moreover, the melting point is lowered by adding Ga; however, part of it forms a low melting-point phase of Ga alone or eutectic with Zn. In order to curb the formation, Sb or Mn is added to partially form an alloy phase with Ga, so that it becomes possible to curb the formation of low melting-point phase due to the addition of Ga.

In a case in which SiC is used for a power semiconductor element, the power semiconductor element operates at higher temperatures as it ought to be operated to enhance its features, in comparison with a case of Si. In a power semiconductor device mounting SiC devices thereon, higher reliability is required as the power semiconductor element, and therefore the merits of the present invention to achieve a highly reliable power semiconductor device become more effective.

Note that, in the present invention, the embodiments can be appropriately modified and/or eliminated without departing from the scope of the invention.

### EXPLANATION OF NUMERALS AND SYMBOLS

Numeral “1” designates a substrate; “2,” Zn based lead-free solder; “3,” power semiconductor element; “4,” resin film; “5,” bonding wire; “6,” bonding pad; and “100,” semiconductor power module.

1. A Zn based lead-free solder, comprising Zn and, in mass percentages relative to the total mass of the solder:
0.05% to 0.2% of chromium (Cr);
0.25% to 1.0% of aluminum (Al);
0.5% to 2.0% of antimony (Sb);
1.0% to 5.8% of germanium (Ge); and
5% to 10% of gallium (Ga).

2. A Zn based lead-free solder, comprising Zn and, in mass percentages relative to the total mass of the solder:
0.05% to 0.2% of chromium (Cr);
0.25% to 1.0% of aluminum (Al);
0.5% to 2.0% of antimony (Sb);
1.0% to 5.8% of germanium (Ge); and
10% to 20% of indium (In).

3. A Zn based lead-free solder, comprising Zn and, in mass percentages relative to the total mass of the solder:
0.05% to 0.2% of chromium (Cr);
0.25% to 1.0% of aluminum (Al);
0.6% to 1.2% of manganese (Mn);
1.0% to 5.8% of germanium (Ge); and
5% to 10% of gallium (Ga).

4. A Zn based lead-free solder, comprising Zn and, in mass percentages relative to the total mass of the solder:
0.05% to 0.2% of chromium (Cr);
0.25% to 1.0% of aluminum (Al);
0.6% to 1.2% of manganese (Mn);
1.0% to 5.8% of germanium (Ge); and
10% to 20% of indium (In).

5. The Zn based lead-free solder of claim 1, further comprising at least one selected from the group consisting of Sn, Bi, P, V, and Si.

6. A semiconductor power module, comprising:
a power semiconductor element bonded on a substrate by the Zn based lead-free solder of claim 1;
a bonding pad formed on a main surface of the power semiconductor element;
a resin film for coating the main surface of the power semiconductor element; and
a bonding wire connected to the bonding pad.

7. The Zn based lead-free solder of claim 2, further comprising at least one selected from the group consisting of Sn, Bi, P, V, and Si.

8. The Zn based lead-free solder of claim 3, further comprising at least one selected from the group consisting of Sn, Bi, P, V, and Si.

9. The Zn based lead-free solder of claim 4, further comprising at least one selected from the group consisting of Sn, Bi, P, V, and Si.

10. A semiconductor power module, comprising:
a power semiconductor element bonded on a substrate by the Zn based lead-free solder of claim 2;
a bonding pad formed on a main surface of the power semiconductor element;
a resin film for coating the main surface of the power semiconductor element; and
a bonding wire connected to the bonding pad.

11. A semiconductor power module, comprising:
a power semiconductor element bonded on a substrate by the Zn based lead-free solder of claim 3;
a bonding pad formed on a main surface of the power semiconductor element;
a resin film for coating the main surface of the power semiconductor element; and
a bonding wire connected to the bonding pad.

12. A semiconductor power module, comprising:
a power semiconductor element bonded on a substrate by the Zn based lead-free solder of claim 4;
a bonding pad formed on a main surface of the power semiconductor element;
a resin film for coating the main surface of the power semiconductor element; and
a bonding wire connected to the bonding pad.
